(19) United States
(12) Patent Application Publication
(10) Pub. No.: US 2012/0313162 A1
(43) Pub. Date: Dec. 13, 2012

(54) SEMICONDUCTOR DEVICE, METHOD FOR MANUFACTURING METAL FILM, AND METHOD FOR MANUFACTURING SEMICONDUCTOR DEVICE

(75) Inventors: Tetsuo Matsuda, Ishikawa-ken (JP); Tomomi Kuraguchi, Ishikawa-ken (JP)

(73) Assignee: Kabushiki Kaisha Toshiba, Tokyo (JP)

(21) Appl. No.: 13/425,226

(22) Filed: Mar. 20, 2012

(30) Foreign Application Priority Data
Jun. 10, 2011 (JP) 2011-130647

(51) Int. Cl. H01L 29/78; H01L 21/336

(52) U.S. Cl. 257/330; 438/270; 257/E29.257; 257/E21.41

(57) ABSTRACT

According to one embodiment, a semiconductor device includes: a semiconductor substrate; an arsenic diffusion layer formed in the semiconductor substrate and containing arsenic; and a metal film formed on the arsenic diffusion layer. The metal film includes at least one metal selected from the group consisting of tungsten, titanium, ruthenium, hafnium, and tantalum, and arsenic.

### CROSS-REFERENCE TO RELATED APPLICATIONS

This application is based upon and claims the benefit of priority from the prior Japanese Patent Application No. 2011-130647, filed on Jun. 10, 2011; the entire contents of which are incorporated herein by reference.

### FIELD

Embodiments described herein relate generally to a semiconductor device, a method for manufacturing metal film, and a method for manufacturing semiconductor device.

### BACKGROUND

It is well known that generally in silicon (Si) based semiconductor devices, a connection between a diffusion layer exhibiting n-type conductivity and a metal is often used. Ideally, this connection between the diffusion layer and the metal has the following properties from the viewpoint of device characteristics, easy miniaturization, and easy production.

(1) At the interface between the n-type diffusion layer and the metal, the concentration of the donor (such as arsenic and phosphorus) being n-type impurity is maximized, and the contact resistance between the metal and the semiconductor is minimized.

(2) The spatial positional relationship between the n-type diffusion layer and the metal is aligned without any excess portion due to misalignment.

However, actually, in the conventional manufacturing technique, formation of the diffusion layer preceding the junction with the metal is typically performed by ion implantation and solid-phase and/or vapor-phase diffusion followed by heat treatment. Hence, at the uppermost surface (subsequently the interface with the metal), the donor concentration is not maximized.

Furthermore, patterning of the diffusion layer and patterning of the metal are performed by separate photolithography processes. Hence, “misalignment” occurs therebetween. In order to compensate for this misalignment, an “alignment margin” is required. This necessitates providing a spatial excess.

Thus, in the conventional manufacturing technique, it is difficult to realize an ideal configuration of the n-type diffusion layer and the metal. The problems such as increased contact resistance, hampered miniaturization, increased production steps, and increased cost have yet to be solved.

Next, typical cases of the above background are described.

As a method for reducing the on-resistance of a low breakdown voltage MOSFET (metal-oxide-semiconductor field-effect transistor), a three-dimensional MOS structure has been regarded promising. In this structure, the channel of the transistor is formed in the thickness direction of the wafer. The width of the channel serving as a current path can be increased to reduce the on-resistance.

Such a structure can indeed reduce the resistance component of the channel. However, the resistance component of the source diffusion layer and the drain diffusion layer placed in the thickness direction of the wafer hampers the reduction of on-resistance.

Thus, there is a trade-off between the reduction of on-resistance due to the increased channel density and the increase of on-resistance due to the source/drain resistance. The trade-off appears when the depth of the three-dimensional MOS structure is approximately 10-20 μm, although it slightly depends on specific design values.

To solve this problem, it can be considered to embed a low resistance metal in the source/drain diffusion layer.

However, the problem arises that the embedding position of the low resistance metal is displaced from the center of the diffusion layer. If the position is displaced, the current path is formed preferentially in the direction in which the source/drain diffusion layer is shorter, i.e., in the direction in which the resistance of the diffusion layer is lower. Thus, the channel in the direction in which the diffusion layer is longer cannot be effectively utilized. This results in increasing the on-resistance and compromising the feature of the 3D MOS structure.

### BRIEF DESCRIPTION OF THE DRAWINGS

FIG. 1 is a schematic sectional view illustrating a semiconductor device according to a first embodiment;

FIG. 2 is a graph illustrating an arsenic concentration in a semiconductor substrate according to the first embodiment;

FIG. 3 is a schematic sectional view illustrating a reaction chamber used in the first embodiment;

FIG. 4 is a schematic sectional view illustrating the semiconductor substrate used in the first embodiment;

FIGS. 5A to 5C are schematic process sectional views illustrating a method for manufacturing a semiconductor device according to the first embodiment;

FIG. 6 is a schematic sectional view illustrating the semiconductor device according to the first embodiment;

FIG. 7 is a schematic sectional view illustrating the semiconductor device according to the first embodiment;

FIG. 8 is a schematic sectional view illustrating a semiconductor device according to a second embodiment;

FIG. 9 is a schematic process sectional view illustrating a method for manufacturing a semiconductor device according to the second embodiment.

FIG. 10 is a schematic sectional view illustrating a semiconductor device according to a third embodiment;

FIGS. 11A to 11C are schematic process sectional views illustrating a method for manufacturing a semiconductor device according to the third embodiment;

FIG. 12 is a schematic sectional view illustrating a semiconductor device according to a second comparative example;

FIG. 13 is a schematic sectional view illustrating a semiconductor device according to a third comparative example;

FIGS. 14A and 14B are schematic process sectional views illustrating a method for manufacturing a semiconductor device according to a fourth comparative example;

FIGS. 15A to 15C are schematic process sectional views illustrating a method for manufacturing a semiconductor device according to the fifth comparative example.

FIG. 16 is a schematic perspective view illustrating a semiconductor device according to a fourth embodiment; and

FIGS. 17A and 17B are schematic process sectional views illustrating a method for manufacturing a semiconductor device according to the fourth embodiment.

### DETAILED DESCRIPTION

In general, according to one embodiment, a semiconductor device includes: a semiconductor substrate; an arsenic diffusion layer formed in the semiconductor substrate and containing arsenic; and a metal film formed on the arsenic diffusion layer. The metal film includes at least one metal selected from the group consisting of tungsten, titanium, ruthenium, hafnium, and tantalum, and arsenic.

In general, according to another embodiment, a method for manufacturing a metal film includes: forming a metal film containing arsenic by a thermal reaction of a gas of a halogen compound containing at least one metal selected from the group consisting of tungsten, molybdenum, titanium, ruthenium, hafnium, and tantalum with a reducing gas represented by R₁R₂R₃As where substituents R₁, R₂, and R₃ each represent hydrogen or an organic group.

In general, according to another embodiment, a method for manufacturing a semiconductor device includes: forming a metal film containing arsenic on a semiconductor substrate by a thermal reaction of a gas of a halogen compound containing at least one metal selected from the group consisting of tungsten, molybdenum, titanium, ruthenium, hafnium, and tantalum with a reducing gas represented by R₁R₂R₃As where substituents R₁, R₂, and R₃ each represent hydrogen or an organic group.

### First Embodiment

Embodiments of the invention will now be described with reference to the drawings.

First, a semiconductor device 1 according to a first embodiment is described.

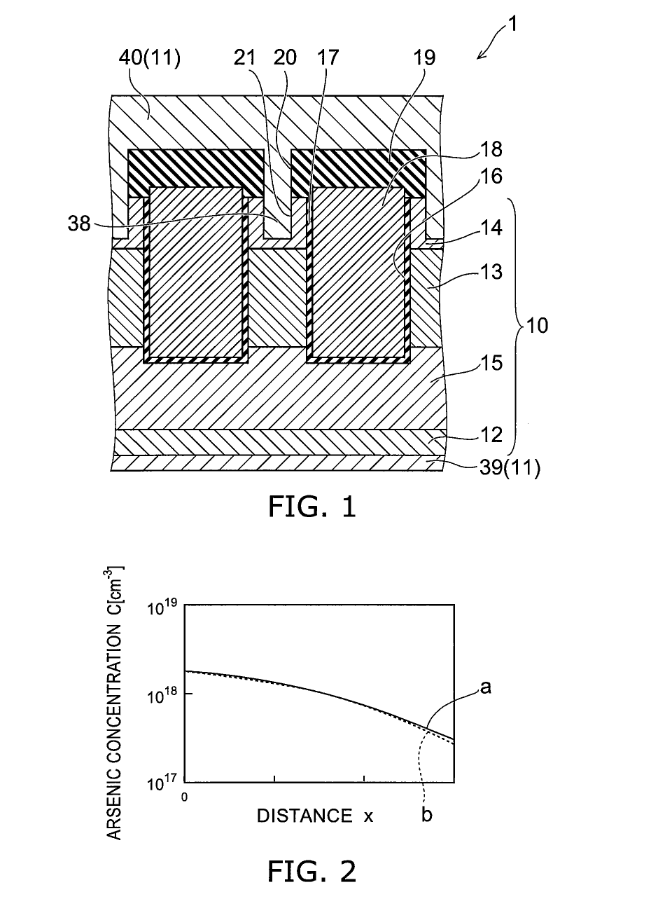

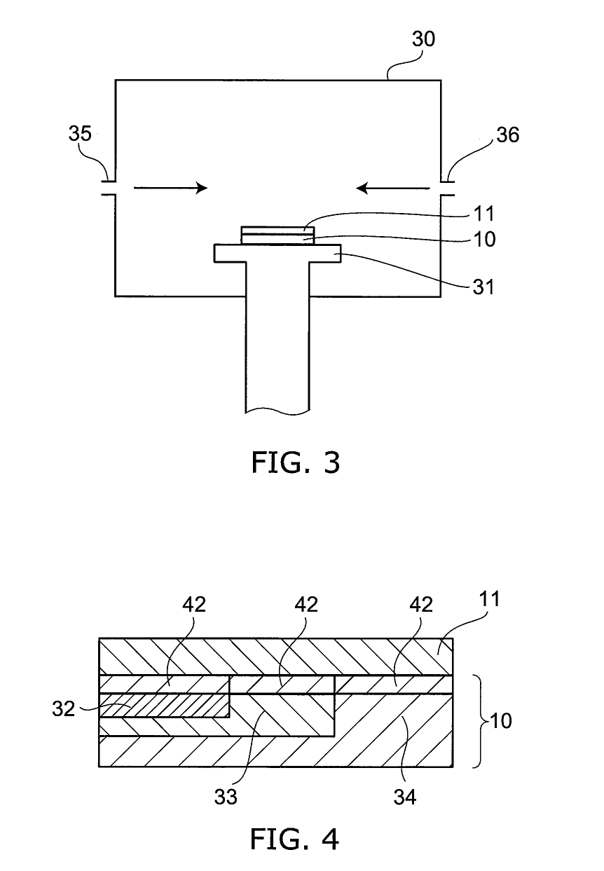

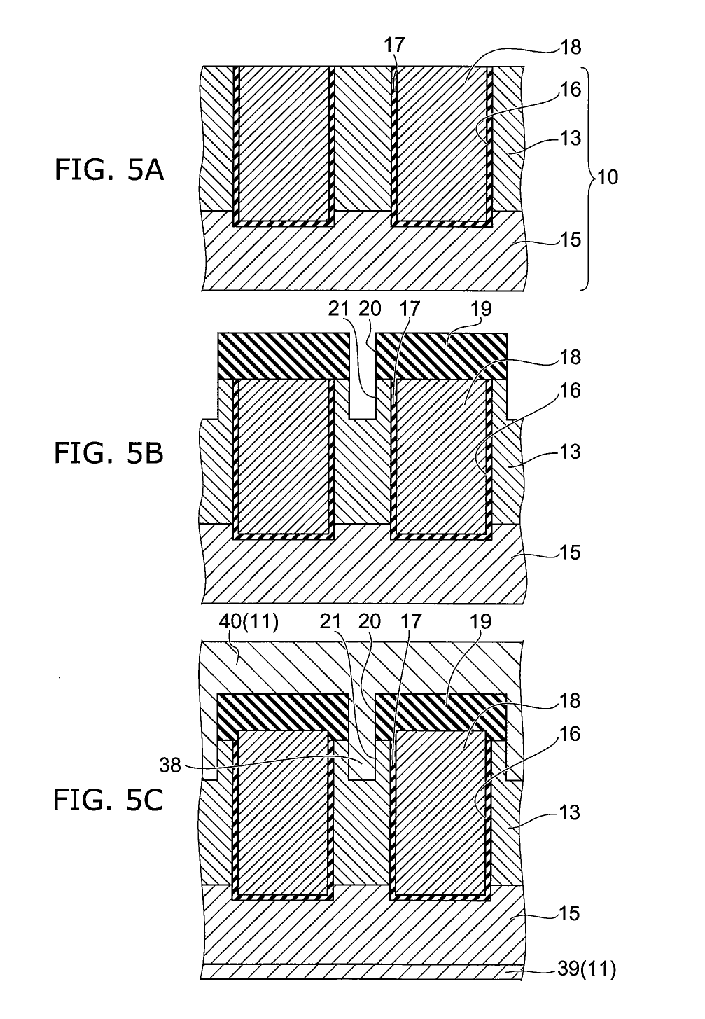

FIG. 1 is a schematic sectional view illustrating a semiconductor device according to the first embodiment. FIG. is a graph illustrating the arsenic concentration in a semiconductor substrate according to the first embodiment. The horizontal axis represents the distance from the metal film in the semiconductor substrate. The vertical axis represents the concentration of arsenic in the semiconductor substrate. FIG. 3 is a schematic sectional view illustrating a reaction chamber used in the first embodiment. FIG. 4 is a schematic sectional view illustrating the semiconductor substrate used in the first embodiment. FIGS. 5A to 5C are schematic process sectional views illustrating a method for manufacturing a semiconductor device according to the first embodiment. FIGS. and 7 are schematic sectional views illustrating the semiconductor device according to the first embodiment.

As shown in FIG. 1, the semiconductor device 1 according to this embodiment is provided in a semiconductor substrate such as a silicon substrate 10. The silicon substrate 10 is doped with impurity such as phosphorus (P). The conductivity type of the silicon substrate 10 doped with phosphorus is n-type.

In contact with the lower surface of the silicon substrate 10, a drain electrode film 39 is formed. The material of the drain electrode film 39 includes at least one metal selected from the group consisting of tungsten (W), molybdenum (Mo), titanium (Ti), ruthenium (Ru), hafnium (Hf), and tantalum (Ta). Furthermore, the drain electrode film 39 includes arsenic (As). Furthermore, in view of connection at chip assembly time, the electrode surface material can be suitably selected except for the metal neighboring the drain diffusion layer 12. For instance, nickel (Ni), vanadium (V), gold (Au), and silver (Ag), and alloys thereof can be suitably selected and stacked.

In a lower portion of the silicon substrate 10, a drain diffusion layer 12 is formed. The drain diffusion layer 12 is doped with arsenic as impurity. Hence, the drain diffusion layer 12 is a diffusion layer of arsenic. The conductivity type of the drain diffusion layer 12 doped with arsenic is n-type. The drain electrode film 39 is formed in contact with the drain diffusion layer 12. Furthermore, the drain electrode film 39 and the drain diffusion layer 12 are in ohmic contact with each other.

A base region 13 is formed to a prescribed depth from the upper surface of the silicon substrate 10. The base region 13 is doped with impurity such as boron (B). The conductivity type of the base region 13 doped with boron is p-type.

Above the base region 13, a source diffusion layer 14 is formed in contact with the base region 13. The source diffusion layer 14 is doped with arsenic as impurity. Hence, the source diffusion layer 14 is a diffusion layer of arsenic. The conductivity type of the source diffusion layer 14 doped with arsenic is n-type.

In the silicon substrate 10, the portion except the drain diffusion layer 12, the base region 13, and the source diffusion layer 14 is referred to as a drift region 15. The conductivity type of the drift region 15 is the same as the conductivity type of the silicon substrate 10, i.e., n-type. The drift region 15 is formed in contact with the drain diffusion layer 12 and the base region 13. The drift region 15 is doped with phosphorus as donor impurity. The concentration of phosphorus in the drift region 15 is made lower than the concentration of arsenic in the drain diffusion layer 12.

In the upper surface of the silicon substrate 10, a plurality of gate trenches 16 extending in one direction are formed in parallel. The gate trench 16 is formed so as to extend from the upper surface of the silicon substrate 10 through the source diffusion layer 14 and the base region 13 into the drift region 15.

On the inner surface of the gate trench 16, a gate insulating film such as a silicon oxide film 17 is formed. Inside the gate trench 16, a conductive material such as polysilicon is embedded. The polysilicon embedded inside the trench 16 functions as a gate electrode 18. The polysilicon is doped with impurity such as phosphorus. The upper end surface of the gate electrode 18 may be projected upward from the upper end surface of the gate trench 16.

On the silicon substrate 10, an interlayer insulating film 19 is formed so as to cover the gate electrode 18. Above the source diffusion layer 14 in the interlayer insulating film 19, an upper contact trench 20 is formed. The upper contact trench 20 is shaped like a trench extending parallel to the extending direction of the gate trench 16. In the silicon substrate 10, a lower contact trench 21 is formed so as to communicate with the upper contact trench 20. The lower contact trench 21 is formed so as to extend into the source diffusion layer 14.

On the interlayer insulating film 19, a source electrode film 40 is formed so as to fill the upper contact trench 20 and the lower contact trench 21. Similarly to the foregoing, the material of the source electrode film 40 includes at least one metal selected from the group consisting of tungsten, titanium, ruthenium, hafnium, and tantalum. Furthermore, the source electrode film 40 includes arsenic. In the source electrode film 40, the portion embedded inside the upper contact trench 20 and the lower contact trench 21 is referred to as a contact 38. The contact 38 is in ohmic contact with the source diffusion layer 14. The configuration as shown in FIG. 1 continues in the direction perpendicular to the page. Hence, the plan view and the side view of the semiconductor device 1 are omitted.

Here, the drain electrode film 39 and the source electrode film 40 are also collectively referred to as a metal film 11.

In this embodiment, the source electrode film 40 is formed inside the upper contact trench 20 and the lower contact trench 21 shaped like a trench. Alternatively, a contact hole shaped like a hole may be formed in the interlayer insulating film 19 and the source diffusion layer 14, and the source electrode film 40 may be formed inside the contact hole. The upper contact trench 20 and the lower contact trench 21 shaped like a trench, and the contact hole shaped like a hole, are referred to as a recess.

The concentration of arsenic in the drain diffusion layer 12 and the source diffusion layer 14 is made higher as the distance from the drain electrode film 39 and the source electrode film 40 is shorter, respectively.

In FIG. 2, the solid line a represents the concentration of arsenic diffused from the drain electrode film 39 in the drain diffusion layer 12. As shown in FIG. 2, the arsenic concentration is higher as the distance from the drain electrode film 39 as a metal film is shorter. The dotted line b represents a complementary error function erfc(x) fitting the concentration of arsenic, where the distance from the metal film is denoted by x. The distribution of the concentration of arsenic diffused from the drain electrode film 39 in the drain diffusion layer 12 is a distribution which can be fitted with a complementary error function as a function of the distance from the drain electrode film 39. Here, as described above, the conductivity type of the drain diffusion layer 12 is n-type, with arsenic and phosphorus distributed therein as donors. Thus, in the case where the drain diffusion layer 12 is previously doped and diffused with arsenic, the final arsenic concentration distribution is determined by the superposition of that previous distribution of arsenic and the distribution which can be fitted with the complementary error function.

Next, the operation of the semiconductor device 1 according to this embodiment is described.

First, a voltage is applied to the gate electrode 18 of the semiconductor device 1. Then, the silicon oxide film 17 provided on the inner surface of the trench 16 acts as a gate insulating film. The base region 13 along the trench 16 of the silicon substrate 10 acts as a channel, and an inversion layer is formed. Then, if a voltage is applied between the source diffusion layer 14 and the drain diffusion layer 12, carriers migrate in the inversion layer, and a current flows. By varying the voltage of the gate electrode 18, the amount of current flowing between the source diffusion layer 14 and the drain diffusion layer 12 is controlled.

In the following, a method for manufacturing the semiconductor device 1 according to this embodiment is described. First, a method for manufacturing a metal film is described.

As shown in FIGS. 3 and 4, a processing stage 31 is provided inside a reaction chamber 30. The reaction chamber 30 is in communication with gas nozzles 35 and 36.

First, on the processing stage 31, a semiconductor substrate such as a silicon substrate 10 is placed. As the silicon substrate 10, a silicon substrate including an n-type diffusion layer 32 doped with phosphorus as impurity, a silicon substrate including a p-type diffusion layer 33 doped with boron as impurity, and a silicon substrate including an intrinsic semiconductor region 34 not doped with impurity are prepared.

Next, evacuation is performed to make the atmosphere in the reaction chamber 30 close to a vacuum. Furthermore, the temperature of the members in the reaction chamber 30 including the silicon substrate 10 is adjusted. The target temperature of the silicon substrate 10 in the reaction chamber 30 can be set in a range of e.g. 200-700° C. The adjustment to such a temperature range can cause reaction of gases introduced into the reaction chamber 30 to form a metal film 11.

Then, into the reaction chamber 30, from the gas nozzle 35, tungsten hexafluoride gas (WF₆) is introduced as a metal source gas. Furthermore, from the gas nozzle 36, arsine (AsH₃) is introduced as a reducing gas for the metal source gas. Here, the gases may be alternately introduced from the same nozzle or separate nozzles. By introducing the aforementioned gases into the reaction chamber 30, the pressure inside the reaction chamber 30 is set to 250 Pa. Furthermore, the temperature of the silicon substrate 10 is set to, for example, 380° C. It should be noted that the pressure inside the reaction chamber 30 and the temperature of the silicon substrate 10 are not limited to these specific values, but can be set appropriately.

Then, thermal reaction of the aforementioned two gases is performed. As a result, a metal film 11 is formed on the silicon substrate 10 at a film formation rate of 12 nm/min. The thermal reaction in this embodiment is a reaction which can be represented by the following formula (1).

WF₆+AsH₃→W+AsF₃+3HF (1)

In this embodiment, arsenic trifluoride (AsF₃), which is a compound of arsenic and fluorine element (F), is not easily vaporized. This is because the boiling point of arsenic trifluoride at 1 atmosphere (760 mmHg) is 56.3° C. Hence, arsenic trifluoride is deposited in the metal film 11.

Furthermore, arsenic trifluoride partly undergoes a thermal decomposition reaction which can be represented by the following formula (2).

AsF₃→As+(3/2)·F₂ (2)

Fluorine (F₂) is easily vaporized. This is because the boiling point of fluorine at 1 atmosphere is −188° C. Hence, arsenic remains in the metal film 11.

The composition of the metal film 11 was analyzed by the Auger electron spectroscopy. The main component was tungsten. Tungsten accounted for 97% of the total. As an admixture, arsenic accounted for 2.7% of the total. As other impurities, hydrogen, oxygen, fluorine and the like were detected in trace amounts.

Similar reaction can also be reproduced in CVD using tungsten hexachloride gas (WCl₆), molybdenum hexafluoride gas (MoF₆), or molybdenum hexachloride gas (MoCl₆) instead of WF₆. Furthermore, it can also be reproduced in a reaction of a gas of a halogen compound containing at least one metal selected from the group consisting of tungsten, molybdenum, titanium, ruthenium, hafnium, and tantalum with a reducing gas represented by R₁R₂R₃As where the substituents R₁, R₂, and R₃ each represent hydrogen or an organic group.

R₁, R₂, and R₃ can be C₆H₅. Hence, the reducing gas represented by R₁R₂R₃As can be (C₆H₅)₃As.

Then, the metal film 11 and the silicon substrate 10 are heat treated. Thus, the arsenic contained in the metal film 11 is diffused into the silicon substrate 10. The portion diffused with arsenic constitutes an arsenic diffusion layer 42. The metal film 11 and the arsenic diffusion layer 42 as shown in this embodiment are applied to the source/drain electrode film and the source/drain diffusion layer in the semiconductor device described later.

### First Comparative Example

Next, a first comparative example is described.

In this comparative example, in the method for forming a metal film, as a reducing gas, silane (SiH₄) is introduced instead of arsine. Hence, in this comparative example, a thermal reaction which can be represented by the following formula (3) occurs.

WF₆+SiH₄→W+SiF₄+2HF+H₂ (3)

As in this comparative example, in the case where silane containing silicon is used as a reducing gas, silicon does not substantially remain in the tungsten film. This is because the vapor pressure of silicon tetrafluoride (SiH₄) in formula (3) is high. That is, the boiling point of silicon tetrafluoride at 1 atmosphere is −94.8° C. Silicon tetrafluoride is evacuated as a gas inside the reaction chamber. Unlike the aforementioned method for manufacturing the metal film 11, the element contained in the reducing gas does not remain.

The method for forming the metal film 11 of this embodiment can form a metal film 11 containing arsenic.

Furthermore, by suitably selecting the temperature, a sufficient film formation rate can be ensured to reduce the film defect density. The film can be caused to contain arsenic in a concentration enough to be diffused into the silicon substrate 10.

In the case of alternately introducing the reaction gases into the reaction chamber, abrupt reaction in the vapor phase can be suppressed. Thus, a significant effect is achieved in improving the film quality and step coverage.

Furthermore, an arsenic diffusion layer 25 can be formed between the intrinsic semiconductor region 34 and the metal film 11. Hence, a uniform and shallow ohmic contact structure can be formed in a self-aligned manner between the intrinsic semiconductor region 34 and the metal film 11, where an electrical contact could not otherwise be formed because of the presence of a Schottky barrier.

Next, a method for manufacturing the semiconductor device 1 based on the method for forming the metal film 11 according to this embodiment is described.

First, as shown in FIG. 5A, a silicon substrate 10 made of e.g. monocrystalline silicon is prepared. The silicon substrate 10 is doped with e.g. phosphorus. Hence, the conductivity type of the silicon substrate 10 doped with phosphorus is n-type.

Next, to a prescribed depth from the upper surface of the silicon substrate 10, impurity such as boron is ion-implanted. Thus, a base region 13 is formed in an upper portion of the silicon substrate 10.

Then, in the upper surface of the silicon substrate 10, a plurality of gate trenches 16 extending in one direction are formed in parallel. The gate trench 16 is formed to a depth such as to penetrate through the base region 13. For instance, the gate trenches 16 are formed as follows. On the silicon substrate 10, a plurality of hard masks extending in one direction are formed in parallel. The hard masks are used as a mask to etch the silicon substrate 10. Thus, the gate trenches 16 are formed.

Then, on the inner surface of the gate trench 16, a gate insulating film such as a silicon oxide film 17 is formed. The silicon oxide film 17 is formed by forming a silicon oxide film on the silicon substrate 10 including the inner surface of the gate trench 16, and then removing the portion except the portion on the inner surface of the gate trench 16.

Next, on the silicon substrate 10, a conductive material such as a polysilicon film is formed so as to fill the inside of the gate trench 16. Then, the portion except the portion inside the gate trench 16 is removed. Thus, polysilicon is embedded inside the gate trench 16. The portion embedded inside the gate trench 16 functions as a gate electrode 18. The polysilicon is doped with impurity such as phosphorus. The polysilicon deposited on the gate trench 16 may be left to form an electrode 18. In this case, the upper end surface of the gate electrode 18 is projected upward from the upper end surface of the gate trench 16.

Next, as shown in FIG. 5B, on the silicon substrate 10, an interlayer insulating film 19 is formed so as to cover the gate electrode 18. The interlayer insulating film can be such as a silicon oxide film and USG (undoped silicate glass). Above a region between the gate trenches 16 in the interlayer insulating film 19, an upper contact trench 20 is formed. The upper contact trench 20 is formed in the shape of a trench extending parallel to the extending direction of the gate trench 16. In the silicon substrate 10, a lower contact trench 21 is formed so as to communicate with the upper contact trench 20. Alternatively, in the interlayer insulating film 19 and the silicon substrate 10, instead of the upper contact trench 20 and the lower contact trench 21, a contact hole may be formed.

Next, as shown in FIG. 5C, on the interlayer insulating film 19, a source electrode film 40 is formed so as to fill the upper contact trench 20 and the lower contact trench 21. In the source electrode film 40, the portion embedded inside the upper contact trench 20 and the lower contact trench 21 is referred to as a contact 38.

Furthermore, on the back surface of the silicon substrate 10, a drain electrode film 39 is formed. The drain electrode film 39 may be formed simultaneously with the source electrode film 40. However, the drain electrode film 39 may be formed independently in a separate step. For instance, the back surface region 15 of the semiconductor substrate 10 may be thinned by cutting or etching (to reduce the resistance of the region 15). The cutting or etching is typically performed after completing the manufacturing process on the front side of the substrate. In this case, the source electrode film 40 and the drain electrode film 39 are formed in two separate steps.

The drain electrode film 39 and the source electrode film 40 are formed by a method similar to the aforementioned method for manufacturing the metal film 11 containing arsenic.

Here, in view of connection at chip assembly time, as the electrode surface material of the drain electrode film 39, Ni, V, Au, and Ag, and alloys thereof may be suitably selected and stacked.

Then, the arsenic contained in the drain electrode film 39 and the source electrode film 40 is diffused into the silicon substrate 10. The method for diffusion can be the rapid thermal anneal (RTA) method. The RTA method performs heat treatment for a short time in a diffusion furnace. The heat treatment temperature can be e.g. a temperature of 800-1000° C. The heat treatment time can be several seconds.

By this heat treatment, the arsenic contained in the silicon substrate 10 is activated to act as a donor. The arsenic diffusion layer constitutes a source diffusion layer 14 and a drain diffusion layer 12.

Thus, as shown in FIG. 1, the semiconductor device 1 is manufactured.

In the semiconductor device 1 according to this embodiment, the concentration of arsenic in the source diffusion layer 14 and the drain diffusion layer 12 is maximized in the portion in contact with the source electrode film 40 and the drain electrode film 39. Thus, the interface resistance between the source electrode film 40 and the source diffusion layer 14, and the interface resistance between the drain electrode film 39 and the drain diffusion layer 12 are low. Accordingly, an ohmic contact is realized. Furthermore, at these interfaces, the resistance is equal everywhere. Hence, the entirety of the source diffusion layer 14 and the drain diffusion layer 12 can be effectively utilized as a current path. Thus, the on-resistance can be reduced. By miniaturization with the resistance of the source diffusion layer 14 and the drain diffusion layer 12 left unchanged, the integration density of the semiconductor device can be increased.

Furthermore, in the method for manufacturing the semiconductor device 1 according to this embodiment, the metal film is formed by the CVD method. Film formation by the CVD method is superior in the performance of step coverage. Hence, the metal film 11 covering fine trenches such as the upper contact trench 20 and the lower contact trench 21 formed in the silicon substrate 10 can be formed.

In the case of alternately introducing the reaction gases into the reaction chamber, abrupt reaction of the gases can be suppressed. Thus, the metal film 11 can be uniformly formed.

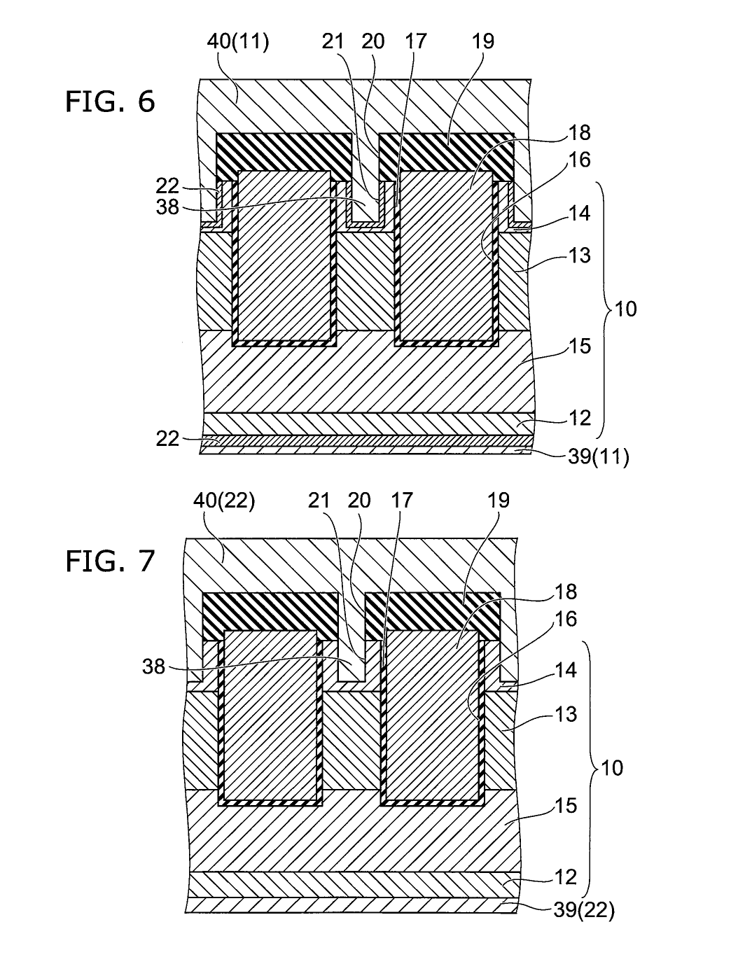

In this embodiment, as shown in FIG. 6, a silicide film 22 may be formed at the interface between the drain diffusion layer 12 and the source diffusion layer 14 in the silicon substrate 10 on one hand and the drain electrode film 39 and the source electrode film 40 on the other. Thus, the interface resistance can be reduced. Furthermore, the thermal stability at the interface can be improved. The silicide can be e.g. tungsten silicide, molybdenum silicide, titanium silicide, ruthenium silicide, hafnium silicide, and tantalum silicide.

In the following, a method for forming a silicide film 22 at the interface is described. First, by a method similar to the aforementioned method for manufacturing the metal film 11, a drain electrode film 39 and a source electrode film 40 are formed. Then, after the aforementioned heat treatment for diffusing arsenic, another heat treatment is performed to form a silicide film 22 at the interface. Tungsten gradually starts to react with silicon at a temperature of approximately 800° C. to form tungsten silicide. Thus, by suitably selecting the aforementioned heating condition for heat treatment, the structure of tungsten source electrode film 40/source diffusion layer 14 or tungsten drain electrode film 39/drain region 12 as shown in FIG. 1 can be turned to the structure of tungsten source electrode film 40/tungsten silicide film 22/source diffusion layer 14 or tungsten drain electrode film 39/tungsten silicide film 22/drain diffusion layer 12 as shown in FIG. 6.

Here, “/” indicates stacking. Thus, “tungsten source electrode film 40/source diffusion layer 14” indicates that the source electrode film 40 of tungsten is stacked on the source diffusion layer 14.

The heating condition for silicidizing a metal can be realized by e.g. heat treatment at a higher temperature than the heat treatment for forming a diffusion layer of arsenic such as the source diffusion layer 14 and the drain diffusion layer 12, or heat treatment for a longer time than the heat treatment for forming a diffusion layer of arsenic.

Furthermore, in this embodiment, as shown in FIG. 7, the entirety of the drain electrode film 39 and the entirety of the source electrode film 40 may be formed from a silicide film 22. This has the effect of improving the thermal stability of the entire contact 38.

In the following, a method for silicidizing the entirety of the drain electrode film 39 and the entirety of the source electrode film 40 is described. First, by a method similar to the aforementioned method for manufacturing the metal film 11, a drain electrode film 39 and a source electrode film 40 are formed. Then, heat treatment is performed at a higher temperature or for a longer time than the aforementioned heat treatment condition. Thus, the structure of tungsten source electrode film 40/source diffusion layer 14 or tungsten drain electrode film 39/drain diffusion layer 12 as shown in FIG. 1 is turned to the structure of tungsten silicide source electrode film 40/source diffusion layer 14 or tungsten silicide drain electrode film 39/drain diffusion layer 12 as shown in FIG. 7.

### Second Embodiment

Next, a second embodiment is described.

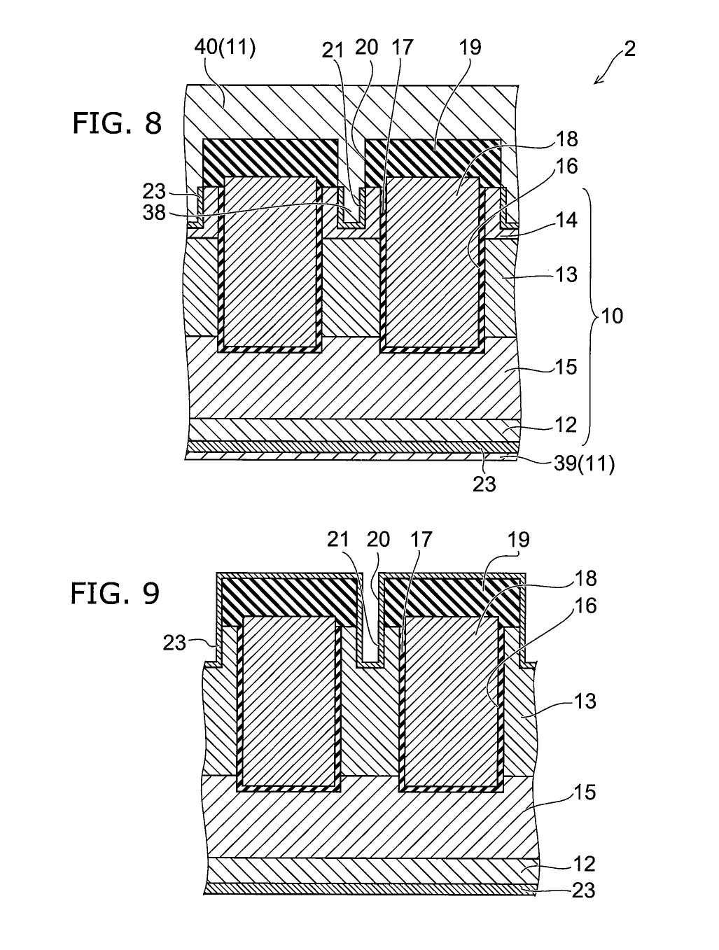

FIG. 8 is a schematic sectional view illustrating a semiconductor device according to the second embodiment. FIG. 9 is a schematic process sectional view illustrating a method for manufacturing a semiconductor device according to the second embodiment.

In this embodiment, a liner film is formed between the silicon substrate 10 on one hand and the drain electrode film 39 and the source electrode film 40 on the other.

As shown in FIG. 8, in the semiconductor device 2 according to this embodiment, a liner film 23 is formed between the source diffusion layer 14 and the drain diffusion layer 12 on one hand and the drain electrode film 39 and the source electrode film 40 on the other. The liner film 23 refers to a film formed between the source diffusion layer 14 and the drain diffusion layer 12 being arsenic diffusion layers on one hand and the drain electrode film 39 and the source electrode film 40 on the other. The liner film 23 includes at least one material selected from the group consisting of titanium, titanium nitride, tantalum, tantalum nitride, ruthenium, silicon oxide, silicon nitride, and SiNH. The configuration and operation other than the foregoing are similar to those of the above first embodiment.

In the following, a method for manufacturing the semiconductor device 2 according to this embodiment is described.

First, similarly to the above first embodiment, the steps shown in FIGS. 5A and 5B are performed. The description of these steps is omitted.

Next, as shown in FIG. 9, a liner film 23 is formed on the silicon substrate 10 including the inner surface of the upper contact trench 20 and the lower contact trench 21 and the back surface of the silicon substrate 10. The material of the liner film 23 can be at least one material selected from the group consisting of titanium, titanium nitride, tantalum, tantalum nitride, ruthenium, silicon oxide, silicon nitride, and SiNH.

The method for forming the liner film 23 can be the thermal CVD method or the plasma enhanced CVD method. Alternatively, the liner film 23 can be formed by oxidation or nitridation of the silicon substrate 10.

The portion of the liner film 23 on the interlayer insulating film 19 is selectively removed. Alternatively, the portion on the interlayer insulating film 19 may be left.

Then, on the interlayer insulating film 19, a source electrode film 40 and a drain electrode film 39 are formed so as to fill the upper contact trench 20 and the lower contact trench 21. In the metal film 11, the portion embedded inside the upper contact trench 20 and the lower contact trench 21 is referred to as a contact 38.

On the back surface of the silicon substrate 10, the drain electrode film 39 is formed. The method for forming the drain electrode film 39 and the source electrode film 40 is similar to that of the above first embodiment.

Then, the arsenic contained in the source electrode film 40 and the drain electrode film 39 is diffused into the silicon substrate 10. The diffusion layer of arsenic constitutes a source diffusion layer 14 and a drain diffusion layer 12. The diffusion of arsenic can be performed through the liner film 23.

Thus, as shown in FIG. 8, the semiconductor device 2 is manufactured.

In the case of forming a metal film such as a tungsten film by the CVD method, the by-products such as fluorine and hydrogen fluoride (HF) may locally corrode the silicon substrate 10. In the semiconductor device 2 according to this embodiment, after forming a liner film 23 on the silicon substrate 10, a tungsten film is formed by the CVD method.

Hence, such corrosion of the silicon substrate 10 by fluorine and hydrogen fluoride can be prevented.

### Third Embodiment

Next, a third embodiment is described.

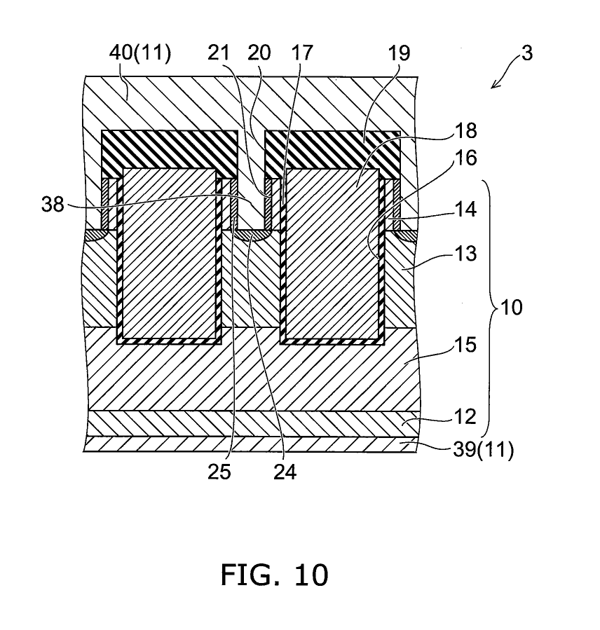

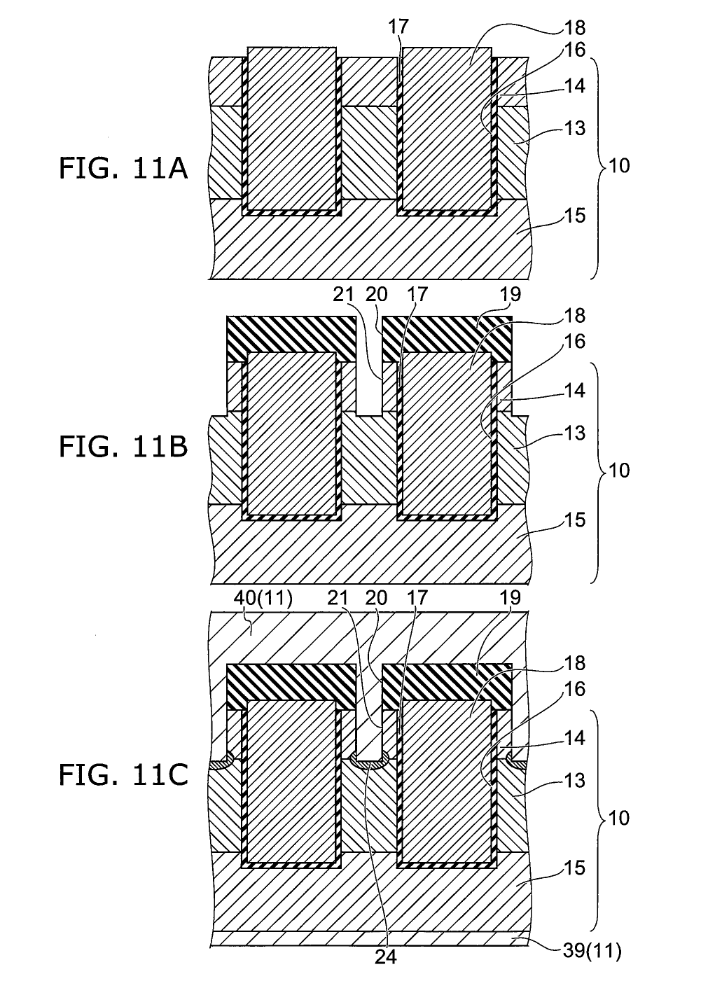

FIG. 10 is a schematic sectional view illustrating a semiconductor device according to the third embodiment. FIGS. 11A to 11C are schematic process sectional views illustrating a method for manufacturing a semiconductor device according to the third embodiment.

As shown in FIG. 10, in the semiconductor device 3 according to this embodiment, the lower contact trench 21 is formed deeply to the base region 13. Furthermore, immediately below the bottom surface of the lower contact trench 21 in the base region 13, a carrier extraction layer 24 is formed.

The carrier extraction layer 24 causes holes remaining in the base region 13 in transition during the off-time of the transistor to be ejected through the contact 38. This can improve the avalanche withstand capability. In order to facilitate ejecting holes, the lower contact trench 21 is formed to the base region 13, and the carrier extraction layer 24 is formed immediately below the bottom surface of the lower contact trench 21. The carrier extraction layer 24 is doped with impurity such as boron serving as acceptor at a higher concentration than the base region 13.

The source diffusion layer 14 in this embodiment is formed by the ion implantation method from above the silicon substrate 10 and thermal diffusion. Hence, the impurity concentration in the source diffusion layer 14 decreases with the depth from the upper surface of the silicon substrate 10.

In the portion of the silicon substrate 10 in contact with the lower contact trench 21, an arsenic diffusion layer 25 is formed

The contact 38 is formed from a source electrode film 40 containing arsenic.

The configuration and operation other than the foregoing are similar to those of the above first embodiment, and hence the description thereof is omitted.

In the following, a method for manufacturing a semiconductor device according to this embodiment is described.

First, similarly to the above first embodiment, the step shown in FIG. 5A is performed. The description of this step is omitted. In this embodiment, the polysilicon deposited on the gate trench 16 is left to form a gate electrode 18. The upper end portion of the gate electrode 18 is projected from the upper end portion of the gate trench 16.

Next, as shown in FIG. 11A, a source diffusion layer 14 is formed. The source diffusion layer 14 is formed by ion-implanting impurity such as phosphorus from above the silicon substrate 10, and then performing thermal diffusion. In the source diffusion layer 14 thus formed, the impurity concentration decreases with the depth from the upper surface of the silicon substrate 10.

Then, as shown in FIG. 11B, on the silicon substrate 10, an interlayer insulating film 19 is formed so as to cover the gate electrode 18. Then, above a region between the gate trenches 16 in the interlayer insulating film 19, an upper contact trench 20 is formed. In the silicon substrate 10, a lower contact trench 21 is formed so as to communicate with the upper contact trench 20. The lower contact trench 21 is formed deeply so as to penetrate through the source diffusion layer 14 to the upper surface of the base region 13.

Then, as shown in FIG. 11C, in the base region 13 at the bottom surface of the lower contact trench 21, a carrier extraction layer 24 is formed. The carrier extraction layer 24 is formed by ion-implanting impurity such as boron from above the silicon substrate 10.

Next, on the interlayer insulating film 19, a source electrode film 40 is formed so as to fill the upper contact trench 20 and the lower contact trench 21. Furthermore, on the back surface of the silicon substrate 10, a drain electrode film 39 is formed.

Then, as shown in FIG. 10, the arsenic contained in the source electrode film 40 and the drain electrode film 39 is diffused into the silicon substrate 10. Thus, in the region of the silicon substrate 10 in contact with the side surface of the lower contact trench 21, an arsenic diffusion layer 25 is formed. Furthermore, in a lower portion of the silicon substrate 10, a drain region 12 is formed.

Thus, the semiconductor device 3 is manufactured.

### Second Comparative Example

Next, a second comparative example is described.

This comparative example is an example of forming a source upper contact 26. Furthermore, the source electrode film 40 and the drain electrode film 39 are formed from a metal film 41 not containing arsenic.

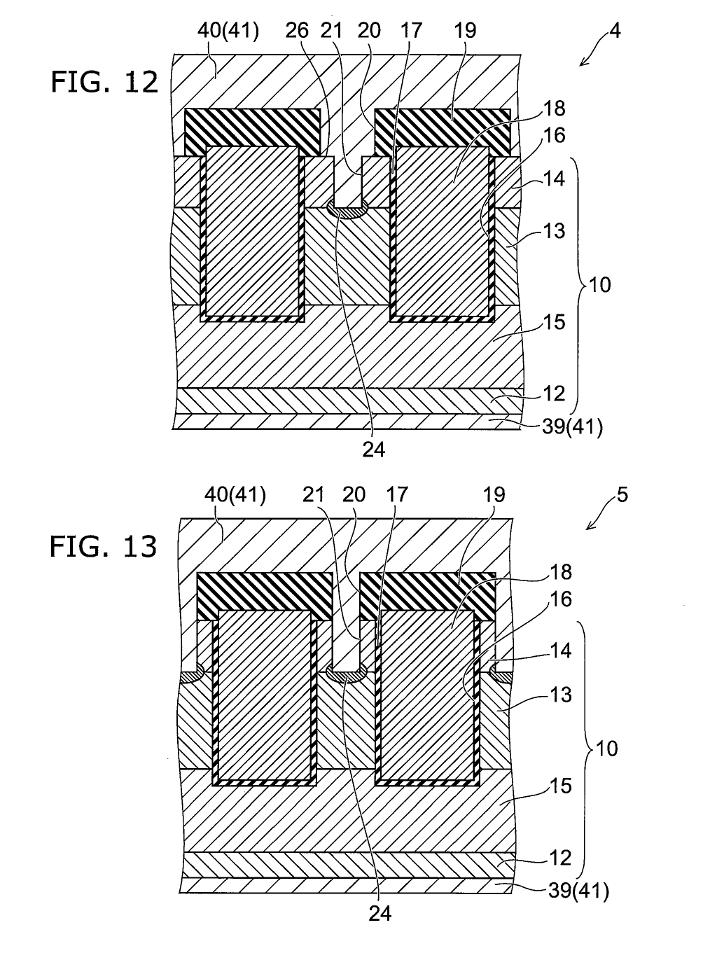

FIG. 12 is a schematic sectional view illustrating a semiconductor device according to the second comparative example.

As shown in FIG. 12, also in the semiconductor device 4 according to this comparative example, the contact trench 21 is formed deeply to the base region 13. Furthermore, in the bottom surface of the contact trench 21, a carrier extraction layer 24 is formed. The source diffusion layer 14 in this embodiment is formed by the ion implantation method from above the silicon substrate 10 and the thermal diffusion method.

Hence, the impurity concentration in the source diffusion layer 14 is maximized at the upper surface of the silicon substrate 10. The concentration decreases with the depth from the upper surface of the silicon substrate 10.

However, unlike the above embodiment, the source electrode film 40 and the drain electrode film 39 are formed from a metal film 41 not containing arsenic. Furthermore, in the portion in contact with the contact trench 21, the arsenic diffusion layer 25 is not formed. Hence, the portion in contact with the side surface of the contact trench 21 has high resistance.

Thus, in order to decrease the on-resistance, the width of the upper contact trench 20 is made wider than the width of the lower contact trench 21. Furthermore, the upper surface of the silicon substrate 10 is exposed at the bottom surface portion of the upper contact trench 20. The exposed portion constitutes a source upper contact 26. Thus, the on-resistance can be kept low.

However, this requires an additional area by the width of the source upper contact 26. Thus, the integration density of the semiconductor device 4 cannot be increased.

### Third Comparative Example

Next, a third comparative example is described.

This comparative example is an example of forming neither the source upper contact 26 nor the arsenic diffusion layer 25. Furthermore, the source electrode film 40 and the drain electrode film 39 are formed from a metal film 41 not containing arsenic.

FIG. 13 is a schematic sectional view illustrating a semiconductor device according to the third comparative example.

As shown in FIG. 13, in the semiconductor device 5 of this comparative example, neither the source upper contact 26 nor the arsenic diffusion layer 25 is formed. Because there is no source upper contact 26, the area can be reduced by the area of the source upper contact 26.

However, with the depth from the upper surface of the silicon substrate 10, the impurity concentration in the source diffusion layer 14 is decreased. Hence, the resistance of the portion in contact with the side surface of the bottom portion of the lower contact trench 21 is increased. This requires increasing the area in order to reduce the resistance. Thus, the integration density of the semiconductor device 5 cannot be increased.

### Fourth Comparative Example

Next, a fourth comparative example is described.

In this comparative example, impurity is doped around the lower contact trench 21. Then, instead of the source electrode film 40 containing arsenic, a metal film 41 not containing arsenic is formed.

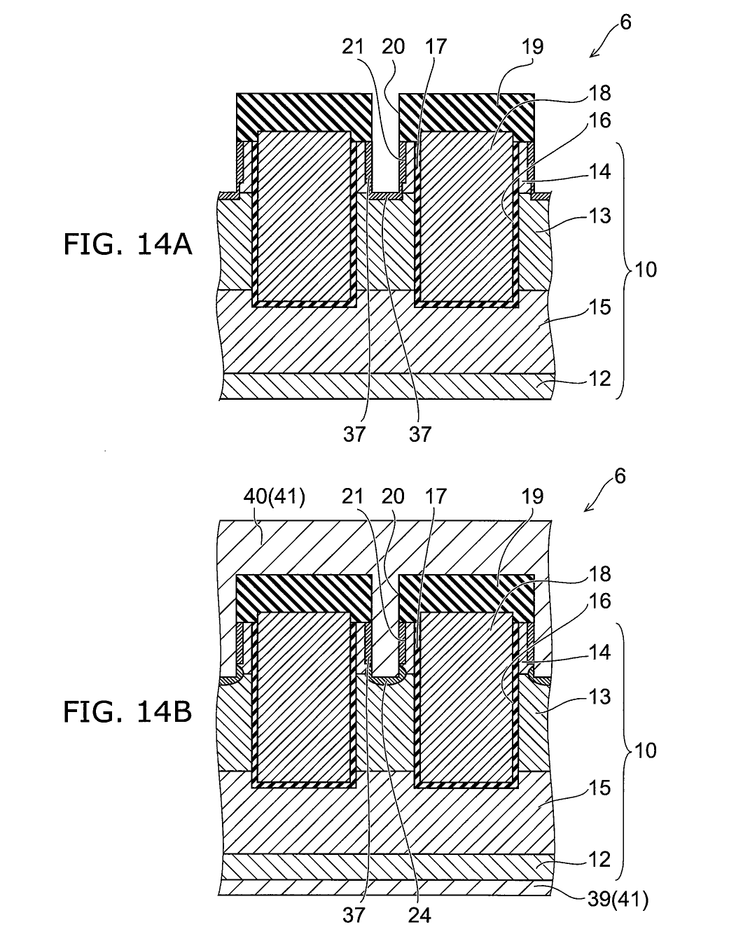

FIGS. 14A and 14B are schematic process sectional views illustrating a method for manufacturing a semiconductor device according to the fourth comparative example.

First, similarly to the above first embodiment, the step shown in FIG. 5A is performed. The description of this step is omitted.

Next, similarly to the above third embodiment, the steps shown in FIGS. 11A and 11B are performed. The description of these steps is omitted.

Then, as shown in FIG. 14A, impurity is doped around the contact trench 21 to form an impurity diffusion layer 37.

The impurity diffusion layer 37 is formed by ion implantation from above the silicon substrate 10 and thermal diffusion. Furthermore, in the bottom portion of the silicon substrate 10, a drain diffusion layer 12 is formed. The drain diffusion layer 12 is also formed by ion implantation and thermal diffusion.

Then, as shown in FIG. 14B, in the base region 13 immediately below the bottom surface of the contact trench 21, a carrier extraction layer 24 is formed.

Next, on the interlayer insulating film 19, a metal film 41 not containing arsenic is formed so as to fill the upper contact trench 20 and the lower contact trench 21. Furthermore, also on the back surface of the silicon substrate 10, a metal film 41 not containing arsenic is formed.

In the semiconductor device 6 according to this comparative example, in the portion of the impurity diffusion layer 37 in contact with the sidewall of the bottom portion of the contact trench 21, the impurity concentration is decreased. This is because the sidewall of the contact trench 21 may fail to be uniformly doped with impurity by ion implantation and vapor-phase diffusion. In the bottom portion of the contact trench 21 with decreased impurity concentration, the contact resistance is increased.

### Fifth Comparative Example

Next, a fifth comparative example is described.

In this comparative example, before forming an upper contact trench 20 and a lower contact trench 21, the semiconductor substrate is doped with impurity to form an impurity diffusion layer 37. Then, a lower contact trench 21 is formed in the impurity diffusion layer 37. As the source electrode film 40 and the drain electrode film 39, a metal film 41 not containing arsenic is used.

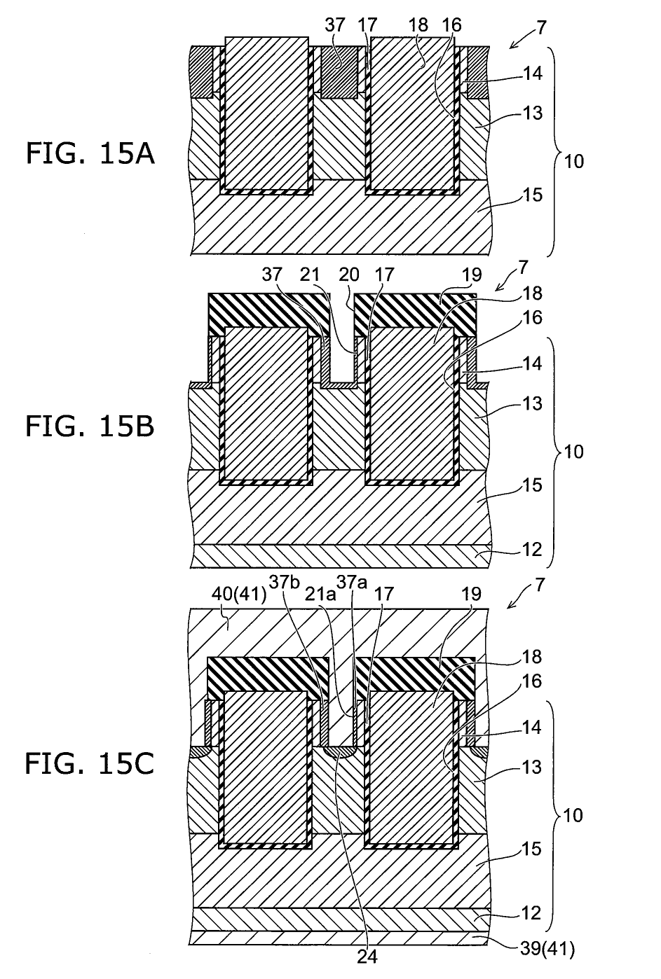

FIGS. 15A to 15C are schematic process sectional views illustrating a method for manufacturing a semiconductor device according to the fifth comparative example.

First, similarly to the above first embodiment, the step shown in FIG. 5A is performed. The description of this step is omitted.

Next, similarly to the above third embodiment, the step shown in FIG. 11A is performed. The description of this step is omitted.

Next, as shown in FIG. 15A, in an upper portion of the silicon substrate 10 between the gate trenches 16, an impurity diffusion layer 37 is formed. The impurity diffusion layer 37 is formed by ion implantation from above the silicon substrate 10 and thermal diffusion.

Then, as shown in FIG. 15B, on the silicon substrate 10, an interlayer insulating film 19 is formed so as to cover the gate electrode 18. Above a region between the gate trenches 16 in the interlayer insulating film 19, an upper contact trench 20 and a lower contact trench 21 are formed. The upper contact trench 20 is formed so as to penetrate through the interlayer insulating film 19. The lower contact trench 21 is formed in the silicon substrate 10 so as to communicate with the upper contact trench 20.

Then, as shown in FIG. 15C, in the base region 13 at the bottom surface of the lower contact trench 21, a carrier extraction layer 24 is formed. The carrier extraction layer 24 is formed by ion-implanting impurity such as boron from above the silicon substrate 10.

Next, on the interlayer insulating film 19, a metal film 41 not containing arsenic is formed so as to fill the upper contact trench 20 and the lower contact trench 21. Furthermore, also on the back surface of the silicon substrate 10, a metal film 41 not containing arsenic is formed.

In this comparative example, the positional relationship between the upper contact trench 20 and the lower contact trench 21 on one hand and the impurity diffusion layer 37 on the other may be varied due to the misalignment of lithography. For instance, in FIG. 15C, the width of the impurity diffusion layer 37a on the right side of the lower contact trench 21a and the width of the impurity diffusion layer 37b on the left side may be made different. Then, the resistance depends on the current path in the diffusion layer.

The semiconductor device 3 according to this embodiment is different from the semiconductor devices 4-7 according to the above second to fifth comparative examples in that the metal film 11 contains arsenic. Furthermore, in the portion in contact with the side surface of the lower contact trench 21, an arsenic diffusion layer 25 is formed. In the case where the source diffusion layer 14 is formed by ion implantation and thermal diffusion, the impurity concentration in the source diffusion layer 14 decreases with the depth from the upper surface of the silicon substrate 10. However, the arsenic diffusion layer 25 is formed at the interface between the contact 38 and the source diffusion layer 14. Hence, the distribution of impurity concentration by the ion implantation and the subsequent thermal diffusion is not reflected. Thus, the resistance of the interface between the contact 38 and the source diffusion layer 14 can be decreased. Hence, there is no need to increase the area of the source diffusion layer 14 in order to reduce the resistance. Thus, the integration density of the semiconductor device 3 can be increased.

Furthermore, in the semiconductor device 3, in the arsenic diffusion layer 25, the concentration of arsenic is maximized in the portion in contact with the source electrode film 40. Thus, the interface resistance between the source electrode film 40 and the arsenic diffusion layer 25 is low. Accordingly, an ohmic contact is realized.

Furthermore, at this interface, the resistance is equal everywhere. Hence, the entirety of the arsenic diffusion layer 25 can be effectively utilized as a current path. Thus, the on-resistance can be reduced.

Furthermore, in the bottom portion of the contact 38, a p-type carrier extraction layer 24 is formed. Hence, the arsenic diffusion layer 25 can be formed only in the portion in contact with the side surface of the contact 38. Thus, the contact 38 can serve the function as an electrode of the source diffusion layer 14 and the function of ejecting holes in the base region 13.

The arsenic diffusion layer 25 can be formed in a self-aligned manner so as to avoid misalignment. Thus, the integration density of the semiconductor device 5 can be increased.

### Fourth Embodiment

Next, a fourth embodiment is described.

The semiconductor device according to this embodiment relates to a three-dimensional MOS.

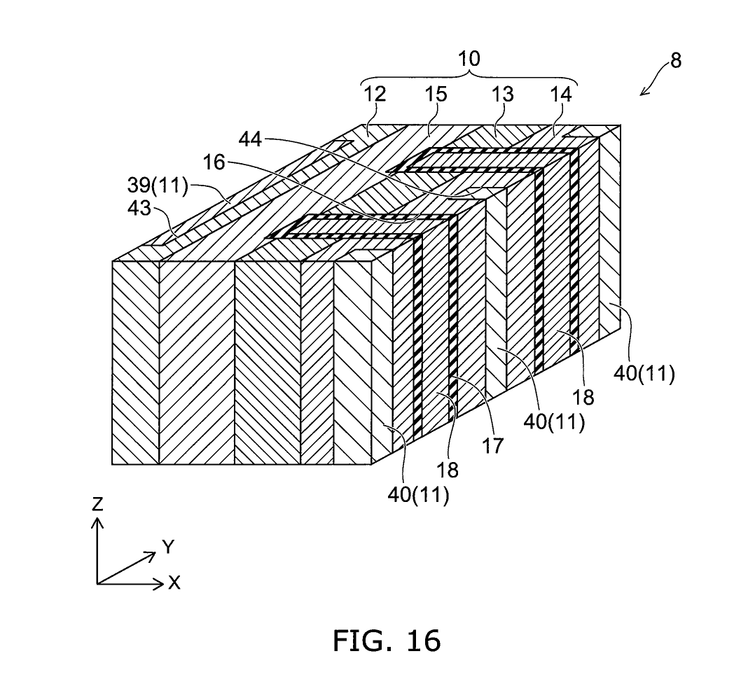

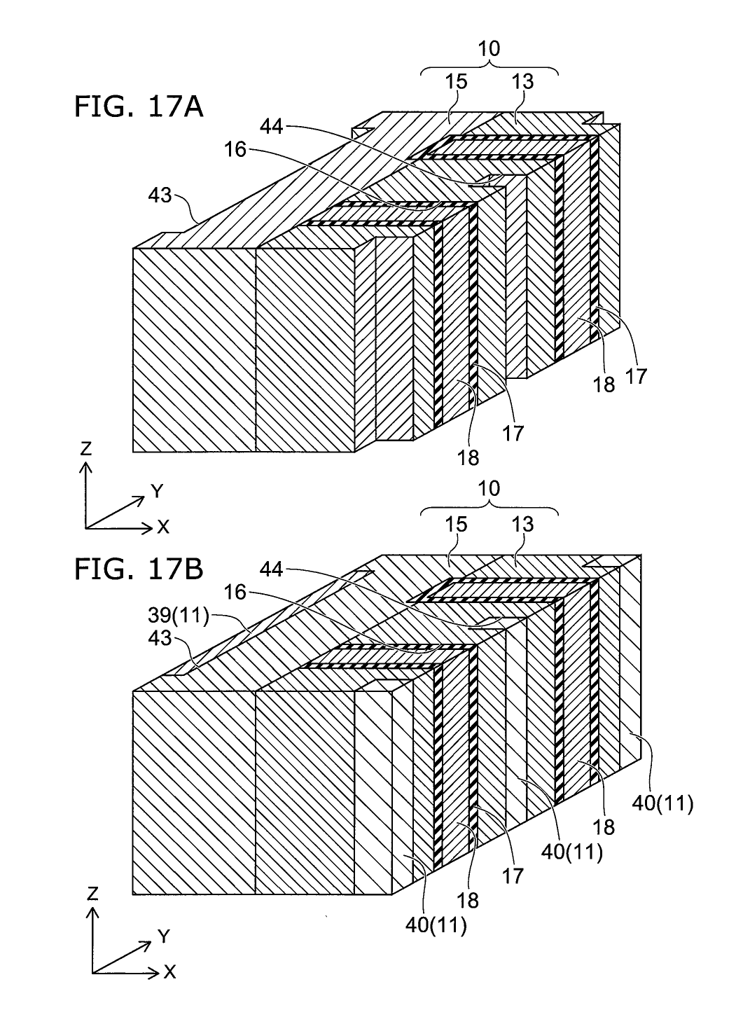

FIG. 16 is a schematic perspective view illustrating a semiconductor device according to the fourth embodiment. FIGS. 17A and 17B are schematic process sectional views illustrating a method for manufacturing a semiconductor device according to the fourth embodiment.

As shown in FIG. 16, the semiconductor device 8 according to this embodiment is provided in a semiconductor substrate such as a silicon substrate 10. In the upper surface of the silicon substrate 10, a plurality of gate trenches 16 extending in one direction are formed. In this embodiment, for convenience of description, an XYZ orthogonal coordinate system is adopted. More specifically, of the directions parallel to the upper surface of the silicon substrate 10, the extending direction of the gate trench 16 is defined as X direction. Of the directions parallel to the upper surface of the silicon substrate 10, the direction orthogonal to the extending direction of the gate trench 16 is defined as Y direction. The direction orthogonal to the upper surface of the silicon substrate 10 is defined as Z direction.

The gate trench 16 is formed to a prescribed depth from the upper surface of the silicon substrate 10.

A drain electrode trench 43 is formed with spacing from the gate trench 16. The drain electrode trench 43 is formed so as to extend in the Y direction. The drain electrode trench 43 is formed with spacing in the X direction from the gate trench 16. The drain electrode trench 43 is formed to a prescribed depth from the upper surface of the silicon substrate 10.

Inside the drain electrode trench 43, a drain electrode film 39 is embedded. The drain electrode film 39 contains arsenic.

In the portion around the drain electrode trench 43 to a prescribed depth from the upper surface of the silicon substrate 10, a drain diffusion layer 12 is formed. The drain diffusion layer 12 is doped with arsenic as impurity.

In the portion between the gate trenches 16 to a prescribed depth from the upper surface of the silicon substrate 10, a base region 13 is formed.

In the portion between the drain diffusion layer 12 and the base region 13 to a prescribed depth from the upper surface of the silicon substrate 10, a drift region 15 is provided. Hence, the drift region 15 is formed in contact with the drain diffusion layer 12 and the base region 13. Furthermore, the drift region 15 is in contact with one X-direction end of the gate trench 16.

In the portion between the gate trenches 16 opposed to the drift region 15 across the base region 13, a source diffusion layer 14 is formed. The source diffusion layer 14 is formed to a prescribed depth from the upper surface of the silicon substrate 10. The source diffusion layer 14 is doped with arsenic as impurity. The source diffusion layer 14 is adjacent to the gate trench 16. In the source diffusion layer 14, a source electrode trench 44 is formed. The source electrode trench 44 is formed to a prescribed depth from the upper surface of the silicon substrate 10.

Inside the source electrode trench 44, a source electrode film 40 is formed. The source electrode film 40 contains arsenic.

On the inner surface of the gate trench 16, a gate insulating film such as a silicon oxide film 17 is formed. Inside the gate trench 16, a conductive material such as polysilicon is embedded. The polysilicon embedded inside the trench 16 functions as a gate electrode 18.

The configuration as shown in FIG. 16 continues in the Y direction. Furthermore, with insulating films and wirings interposed, the configuration may continue in the X direction.

The operation of the semiconductor device 8 according to this embodiment is similar to that of the semiconductor device 1 according to the above first embodiment in which the direction of the current flowing in the channel is set to the X direction of the silicon substrate 10.

In the following, a method for manufacturing a semiconductor device according to this embodiment is described.

First, as shown in FIG. 17A, a silicon substrate 10 is prepared. The silicon substrate 10 is doped with e.g. phosphorus.

Next, in a prescribed region from the upper surface of the silicon substrate 10, to a prescribed depth, impurity such as boron is ion-implanted. The ion implantation is performed on the silicon substrate 10 using a mask including a prescribed opening. Thus, a base region 13 is formed in an upper portion of the silicon substrate 10.

Then, in the upper surface of the silicon substrate 10, a plurality of gate trenches 16 extending in one direction such as the X direction are formed in parallel. The gate trench 16 is formed so as to divide the base region 13 in the X direction. The gate trench 16 is formed to a prescribed depth from the upper surface of the silicon substrate 10.

Then, on the inner surface of the gate trench 16, a gate insulating film such as a silicon oxide film 17 is formed.

Next, polysilicon is embedded inside the gate trench 16. The portion embedded inside the gate trench 16 functions as a gate electrode 18.

Then, in the base region 13 between the gate trenches 16, a source electrode trench 44 is formed with spacing from the gate trenches 16. The source electrode trench 44 is formed to a prescribed depth from the upper surface of the silicon substrate 10.

Next, as shown in FIG. 17B, in the drain electrode trench 43 and the source electrode trench 44, a metal film 11 containing arsenic is embedded to form a drain electrode film 39 and a source electrode film 40. The metal film 11 is formed by a method similar to that of the above first embodiment.

Then, as shown in FIG. 16, the arsenic contained in the drain electrode film 39 and the source electrode film 40 is diffused into the silicon substrate 10. Thus, a drain diffusion layer 12 and a source diffusion layer 14 are formed. The drain diffusion layer 12 is formed in a portion around the drain electrode trench 43 to a prescribed depth from the upper surface of the silicon substrate 10. The source diffusion layer is adjacent to the gate trench 16 in a portion around the electrode trench 44 to a prescribed depth from the upper surface of the silicon substrate 10.

Thus, as shown in FIG. 16, the semiconductor device 8 is manufactured.

In the semiconductor device 8 according to this embodiment, the source diffusion layer 14 and the drain diffusion layer 12 are formed by diffusion of arsenic from the source electrode film 40 and the drain electrode film 39. Hence, as compared with the case of formation by the ion implantation method from above the upper surface of the silicon substrate 10, the dopant concentration of the source diffusion layer 14 and the drain diffusion layer 12 in the thickness direction of the silicon substrate 10 can be made more uniform. Thus, the resistance in the current path can be made uniform.

Furthermore, with the length between the source and the drain kept constant, the MOS structure can be extended in the thickness direction of the silicon substrate 10. Thus, without increasing the on-resistance, the integration density of the MOS structure can be increased.

Furthermore, in the semiconductor device 8, the position of the metal film 11 embedded in the electrode trenches 43 and 44 is located at the center of the drain diffusion layer 12 and the source diffusion layer 14. If the position is displaced from the center of the diffusion layer, the current path is formed preferentially in the direction in which the diffusion layer is shorter, i.e., in the direction in which the resistance of the diffusion layer is lower. However, in this embodiment, the diffusion layer is located at the center. Hence, the current path can be made uniform. Thus, the on-resistance can be reduced.

The embodiments described above can realize a semiconductor device, a method for manufacturing a metal film, and a method for manufacturing a semiconductor device capable of increasing the integration density.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor substrate;
an arsenic diffusion layer formed in the semiconductor substrate and containing arsenic; and
a metal film formed on the arsenic diffusion layer,
the metal film including at least one metal selected from the group consisting of tungsten, titanium, ruthenium, hafnium, and tantalum, and arsenic.

2. The device according to claim 1, wherein arsenic concentration in the arsenic diffusion layer is higher as distance from the metal film is shorter.

3. The device according to claim 1, wherein the metal film is formed in a recess of the arsenic diffusion layer.

4. The device according to claim 1, wherein
the semiconductor substrate includes silicon, and
at least a portion of the metal film in contact with the arsenic diffusion layer is made of a silicide of the metal.

5. The device according to claim 1, further comprising:
a liner film provided between the metal film and the arsenic diffusion layer, and
the liner film is a film including at least one material selected from the group consisting of titanium, titanium nitride, tantalum, tantalum nitride, ruthenium, silicon oxide, silicon nitride, and SiNH.

6. The device according to claim 1, further comprising:
a p-type base region formed in the semiconductor substrate;
an n-type drain diffusion layer formed in a lower portion of the semiconductor substrate;
an n-type drift region formed between the base region and the drain diffusion layer of the semiconductor substrate and having a lower concentration of donor impurity than the drain diffusion layer;
a gate trench formed from an upper surface of the semiconductor substrate and penetrating through the base region;
a gate insulating film formed on an inner surface of the gate trench; and
a gate electrode embedded inside the gate trench,
wherein the arsenic diffusion layer is formed above the base region and adjacent to the gate trench.

7. The device according to claim 1, further comprising:
a plurality of gate trenches formed to a prescribed depth from an upper surface of the semiconductor substrate so as to extend in one direction coplanar with the semiconductor substrate;
a p-type base region formed in a portion between the gate trenches to a prescribed depth from the upper surface of the semiconductor substrate;
an n-type drift region formed to a prescribed depth from the upper surface of the semiconductor substrate, the drift region being formed in contact with the base region and one end in the one direction of the gate trench and having a lower concentration of donor impurity than the arsenic diffusion layer;
a gate insulating film formed on an inner surface of the gate trench; and
a gate electrode embedded inside the gate trench,
wherein the arsenic diffusion layer is formed in at least one of a portion opposed to the drift region across the base region, the portion being adjacent to the gate trench between the gate trenches, and a portion opposed to the base region across the drift region and spaced in the one direction of the gate trench, and
the metal film is formed in a recess of the arsenic diffusion layer.

8. The device according to claim 1, further comprising:
an n-type source diffusion layer formed in an upper portion of the semiconductor substrate;
a p-type base region formed below the source diffusion layer in the semiconductor substrate;
an n-type drain diffusion layer formed in a lower portion of the semiconductor substrate;
an n-type drift region formed between the base region and the drain diffusion layer of the semiconductor substrate and having a lower concentration of donor impurity than the drain diffusion layer;
a plurality of gate trenches formed from an upper surface of the semiconductor substrate and penetrating through the source diffusion layer and the base region;
a gate insulating film formed on an inner surface of the gate trench;
a gate electrode embedded inside the gate trench;
a contact trench formed from the upper surface of the semiconductor substrate and penetrating through the source diffusion layer to the base region;
a p-type carrier extraction layer formed immediately below the contact trench and having a higher concentration of acceptor impurity than the base region; and
an interlayer insulating film provided on the semiconductor substrate so as to cover the gate electrode,
wherein the metal film is formed in a portion of the interlayer insulating film on the contact trench and in the contact trench and connected to the carrier extraction layer, and
the arsenic diffusion layer is formed in a portion in contact with a side surface of the contact trench.

9. A method for manufacturing a metal film, comprising:
forming a metal film containing arsenic by a thermal reaction of a gas of a halogen compound containing at least one metal selected from the group consisting of tungsten, molybdenum, titanium, ruthenium, hafnium, and tantalum with a reducing gas represented by R₁R₂R₃As where substituents R₂, and R₃ each represent hydrogen or an organic group.

10. A method for manufacturing a semiconductor device, comprising:
forming a metal film containing arsenic on a semiconductor substrate by a thermal reaction of a gas of a halogen compound containing at least one metal selected from the group consisting of tungsten, molybdenum, titanium, ruthenium, hafnium, and tantalum with a reducing gas represented by R₁R₂R₃As where substituents R₁, R₂, and R₃ each represent hydrogen or an organic group.

11. The method according to claim 10, further comprising:
forming an arsenic diffusion layer by diffusing the arsenic contained in the metal film into the semiconductor substrate.

12. The method according to claim 10, further comprising:
forming a recess in the semiconductor substrate,
wherein in the forming a metal film, the metal film is formed so as to fill the recess.

13. The method according to claim 10, wherein
the semiconductor substrate includes silicon, and
the method further comprises:
turning at least an interface of the metal film with the semiconductor substrate to a silicide of the metal constituting the metal film by heat treating the semiconductor substrate and the metal film.

14. The method according to claim 10, further comprising, before the forming the metal film on the semiconductor substrate:
forming a liner film on the semiconductor substrate, the liner film including at least one material selected from the group consisting of titanium, titanium nitride, tantalum, tantalum nitride, ruthenium, silicon oxide, silicon nitride, and SiNH.

15. The method according to claim 11, further comprising:
forming a p-type base region in an upper portion of the semiconductor substrate;
forming a plurality of gate trenches penetrating through the base region in the semiconductor substrate;
forming a gate insulating film on an inner surface of the gate trench;
forming a gate electrode by embedding a conductive material inside the gate trench;
forming an interlayer insulating film on the semiconductor substrate so as to cover the gate electrode; and
forming a contact trench between the gate trenches in an upper portion of the semiconductor substrate and the interlayer insulating film,
wherein in the forming a metal film, a contact is formed by embedding the metal film in the contact trench, and
in the forming an arsenic diffusion layer, a source diffusion layer including the arsenic diffusion layer is formed in contact with the base region by diffusing the arsenic contained in the contact into the semiconductor substrate by heat treating the semiconductor substrate.

16. The method according to claim 11, further comprising:
selectively forming a p-type base region in an upper portion of the semiconductor substrate;
forming a plurality of gate trenches in an upper surface of the semiconductor substrate so as to extend in one direction coplanar with the semiconductor substrate and to divide the base region;
forming a drain electrode trench in a portion spaced in the one direction from the gate trench to a prescribed depth from the upper surface of the semiconductor substrate;
forming a source electrode trench in a portion opposed to the drain electrode trench across the base region between the gate trenches to a prescribed depth from the upper surface of the semiconductor substrate;
forming a gate insulating film on an inner surface of the gate trench; and
forming a gate electrode by embedding a conductive material inside the gate trench,
wherein in the forming a metal film, the metal film is embedded in at least one of the drain electrode trench and the source electrode trench, and
in the forming an arsenic diffusion layer, at least one of a drain diffusion layer and a source diffusion layer including the arsenic diffusion layer is formed by diffusing the arsenic contained in the metal film into the semiconductor substrate by heat treating the semiconductor substrate.

17. The method according to claim 11, further comprising:
forming a p-type base region in an upper portion of the semiconductor substrate;
forming a source diffusion layer in an upper portion of the base region in the semiconductor substrate;
forming a plurality of gate trenches penetrating through the base region and the source diffusion layer in the semiconductor substrate;
forming a gate insulating film on an inner surface of the gate trench;
forming a gate electrode by embedding a conductive material inside the gate trench;
forming an interlayer insulating film on the semiconductor substrate so as to cover the gate electrode;
forming a contact trench between the gate trenches in an upper portion of the semiconductor substrate and the interlayer insulating film; and
forming a carrier extraction layer immediately below a bottom surface of the contact trench,
wherein in the forming a metal film, a contact is formed by embedding the metal film in the contact trench, and
in the forming an arsenic diffusion layer, the arsenic diffusion layer is formed in a portion of the semiconductor substrate in contact with a side surface of the contact by diffusing the arsenic contained in the contact into the semiconductor substrate by heat treating the semiconductor substrate.

18. The method according to claim 10, wherein temperature of the thermal reaction is set to within a range of 200-700° C.

19. The method according to claim 10, wherein the gas of the halogen compound is a gas including at least one selected from the group consisting of tungsten hexafluoride gas (WF₆), tungsten hexachloride gas (WCl₆), molybdenum hexafluoride gas (MoF₆), and molybdenum hexachloride gas (MoCl₆).

20. The method according to claim 10, wherein the reducing gas is arsine gas.
